(19) United States
(12) Patent Application Publication
(10) Pub. No.: US 2006/0050081 A1
(43) Pub. Date: Mar. 9, 2006

(54) Color conversion filter substrate and a multicolor light emitting device employing the substrate

(75) Inventors: Makoto Kobayashi, Nagano (JP); Koji Kawaguchi, Nagano (JP); Yukinori Kawamura, Nagano (JP); Kenya Sakurai, Nagano (JP)

Correspondence Address: ROSSI, KIMMS & McDOWELL LLP., P.O. BOX 826, ASHBURN, VA, 20146-0826, US

(73) Assignee: Fuji Electric Holdings Co., Ltd., Kawasaki-ku (JP)

(21) Appl. No.: 11/211,142

(22) Filed: Aug. 24, 2005

(30) Foreign Application Priority Data
Aug. 24, 2004 (JP) JP 2004-244168
Dec. 7, 2004 (JP) JP 2004-354460
Mar. 29, 2005 (JP) JP 2005-096395

(51) Int. Cl. G09G 5/02

(52) U.S. Cl. 345/597

(57) ABSTRACT

A color conversion filter substrate is disclosed that has satisfactory durability and that allows the light after color conversion to be extracted with high efficiency and prevents the decay of intensity of fluorescent light accompanied by light illumination by suppressing, with high probability, the reaction between the dye in an excited state and the matrix. A color conversion filter substrate of the invention includes a transparent support substrate, at least two types of color filters, and at least one type of color conversion filter. The color conversion filter includes a dye dispersed in a matrix, the dye absorbing light with a wavelength and emitting light containing a wavelength different from the absorbed wavelength. The color conversion filter has a refractive index in a range of 1.30 to 1.48. The matrix of the color conversion filter contains a straight type silicone polymer or a resin-modified type silicone polymer.

### CROSS REFERENCE TO RELATED APPLICATIONS

This application is based on, and claims priority to, Japanese Applications No. 2004-244168, filed on Aug. 24, 2004, No. 2004-354460, filed on Dec. 7, 2004, and No. 2005-096395, filed on Mar. 29, 2005, the contents of which are incorporated herein by reference.

### BACKGROUND OF THE INVENTION

A. Field of the Invention

The present invention relates to a color conversion filter substrate allowing multicolor display and a multicolor light emitting device employing the color conversion filter substrate. The multicolor light emitting devices employing the color conversion filter substrate can be applied to displays in image sensors, personal computers, word processors, TVs, audio equipment, video equipment, car navigations telephones, mobile terminals, and measuring instruments for commerce.

B. Description of the Related Art

Various methods for constituting a full color display system using an electric field-driven light emitting device have been proposed, including a three color light emitting method, a color filter method, and a color conversion method. The three color light emitting method activates light emitting elements each emitting red, blue, or green color by applying an electric field. The color filter method displays red, blue, and green colors by cutting white light with color filters. The color conversion method uses filters containing fluorescent dye that absorbs near ultraviolet light, blue light, blue-green light, or white light and emits light in the visible light range by converting wavelength distribution.

Among the methods, the color conversion method can achieve high color reproducibility and efficiency, and it is said to be relatively easy to achieve a large scale display because the electric field-driven light emitting element may be monochromatic, which is different from the three color light emitting method. Thus, the color conversion method is promising as a candidate of a next generation display system. A drawback of the color conversion method is that only conversion from short wavelength light to long wavelength light is possible and the reverse conversion is impossible. This drawback is based on the law of energy conservation and is inevitable so far as one incident photon is converted to one output photon. If a multi-photon process is utilized involving two or more photons, shorter wavelength light could be obtained by color conversion. The multi-photon process, however, requires extraordinarily intense light (the intensity so that two photons are superposed at one fluorescent dye molecule). Such an intense light can be obtained today only by laser. Consequently, the multi-photon process cannot be employed in the color conversion method at present.

One of the important requirements for practical application of color display is to attain high brightness. The factors affecting the brightness in the color conversion method include light emitting performance of a light source (for example, an organic EL device) and light conversion performance of a fluorescent dye. In addition, the improvement of efficiency of extraction of light is a factor that has been taken up as an important problem. Among these factors, the organic EL device used for a light source, for example, has nearly reached a limit in external quantum yield. Color conversion efficiency of fluorescent dyes has also reached approximately a theoretical limit. Therefore, improvement in the efficiency in extracting light is eagerly desired to achieve high brightness in the color display using the color conversion method.

Now, consider a planar light emitting body having a refractive index n₁, with a light intensity in the light emitting body Pc (unit: number of photons s⁻¹) assuming isotropic light emission. In measuring the emitting light using a radiance meter placed in the atmosphere (the radiance meter measuring the number of photons per unit solid angle in a very narrow angle region around the vertical line to the plane of the light emitting body), the brightness Le (unit: number of photons Sr⁻¹ m⁻²s⁻¹) measured by the radiance meter is given by equation (1) below, taking the expansion of solid angle due to refractive index of the light emitting body into account.

Mathematical Formula 1

$${L}_{e} = \frac{1}{4 π} \frac{1}{{n}_{1}^{2}} {P}_{c} \qquad ( 1 )$$

Equation (1) indicates that a light emitting body with a smaller refractive index n₁ emits light with higher brightness Le. Comparing the case n₁=1.4 and the case n₁=1.5, the brightness Le differs by about 13%. Simply stated, the smaller the refractive index of a light emitting body, the brighter the light emitting body is observed to be.

However, there is another point to be taken into consideration in the case of the color conversion method. In a color conversion filter containing a fluorescent dye, functioning as a light emitting body activated by the fluorescent dye, the emitted light intensity depends on the incident light. Consequently, the light transmission from the light source to the color conversion filter must be considered. That is, the change in the amount of incident light into the color conversion filter must be considered when the refractive index of the color filter is changed. The rate of incidence n₁ of light from a layer 2 having a refractive index n₂ to a layer 1 having a refractive index n₁ is given by Equation (2) below. (See Akiyoshi Mikami, “Material Technologies and Fabrication of Devices in Organic EL Display” (in Japanese), published by Technical Information Institute Co., Ltd., p 25.)

Mathematical Formula 2

$${η}_{0} = 1 - \sqrt{1 - \frac{{n}_{1}^{2}}{{n}_{2}^{2}}} \qquad ( 2 )$$

The intensity of incident light in the layer 1 P₁ (unit: number of photons s⁻¹) is given by Equation (3) using the light intensity in the layer 2 P₂ (unit: number of photons s⁻¹).
P₁=η₀P₂ (3)

The layer 2 is regarded as a light source and the layer 1 is regarded as a color conversion filter. The incident light to the color conversion filter is absorbed by the fluorescent dye and converted to light with a different hue. The intensity of the converted light Pc is given by Equation (4) below, using an absorption coefficient Ka of the fluorescent dye and a quantum yield η_{c} of fluorescent light of the fluorescent dye.
P_{c}=Kₐη_{c}P₁ (4)

Substituting Equations (2) through (4) into Equation (1), Equation (5) is obtained.

Mathematical Formula 3

$${L}_{e} = \frac{1}{4 π} \frac{1}{{n}_{1}^{2}} {K}_{a} {η}_{c} ( 1 - \sqrt{1 - \frac{{n}_{1}^{2}}{{n}_{2}^{2}}} ) {P}_{2} \qquad ( 5 )$$

FIG. 4 is a graph showing variation of brightness Le associated with variation of refractive index n₁ of the layer 1 when the refractive index n₂ of the layer 2 is 2.0, which is a typical value of a refractive index of an organic EL layer in a common organic EL device. It is seen from FIG. 4 that the Le increases as the refractive index of the layer 1 (color conversion filter) approaches the refractive index of the layer 2 (organic EL layer). Thus, the derivation of mathematical equations based on conventional knowledge leads to a result that the efficiency in extracting light (the ratio of Le to P₂) is enhanced as the refractive index of a color conversion filter approaches the refractive index of an organic EL layer.

Requirements for a color display include high stability as well as high brightness, efficiency, and color reproducibility. It is, however, known that the brightness of fluorescence decreases with irradiation of light at a wavelength to excite an organic fluorescent dye in a color conversion filter dispersing the dye in polymer resin. (See Japanese Patent No. 2795932.) This presumably is caused by deactivation of the dye in a reaction with the polymer resin component and is not caused by transfer of the dye from an excited state to a basic state associated with the emission of fluorescence.

For the purpose of avoiding the deactivation of fluorescent dye, it has been proposed to disperse inactive fine particles including the fluorescent dye in a polymer resin (Japanese Unexamined Patent Application Publication No. 2000-212554). This means does not thoroughly inhibit yet the reaction between the dye and the resin around the surface of the fine particle. Thus, a color conversion filter has not been obtained that exhibits satisfactory durability in applications that need durability of several tens of thousand hours, such as large area display TVs.

Unfortunately, the efficiency improvement utilizing high refractive index of a color conversion filter has not been demonstrated yet. That is presumably due to some factors other than the knowledge described above affecting the transfer of light. Accordingly, an object of the present invention is to provide a color conversion filter substrate that achieves high efficiency in the light transfer from a light source and in extraction of light from a color conversion filter. Another object of the invention is to provide a color conversion filter substrate exhibiting satisfactory durability by suppressing with high probability the reaction between the dye in an excited state and the matrix of the filter, the reaction being a principal cause of degradation of resistance to light of the color conversion filter.

### SUMMARY OF THE INVENTION

The inventors of the present invention took notice of the light transfer from the organic EL device to the color conversion filter and made extensive studies, and found that the problem of efficiency improvement in the light transfer from the light source and the extraction of light from the color conversion filter can be solved by employing a color conversion filter having a refractive index in a range of 1.30 to 1.48.

The inventors also found that the problems of suppressing with high probability the reaction between the dye in an excited state and the matrix and attaining satisfactory durability can be solved by employing a matrix for the fluorescent dye composed of a straight type silicone polymer or a resin-modified type silicone polymer, either of these having a siloxane bond, for giving the filter a refractive index as described above.

Combination of the color conversion filter substrate as described above and an organic EL device provides a multicolor light emitting device of high brilliance and a long life.

The above-described construction of the invention provides a color conversion filter with satisfactory durability that allows the light after color conversion to be extracted with high efficiency and prevents the decay of intensity of fluorescent light associated with light illumination. In addition, use of the color conversion filter of the invention provides a multicolor light emitting device that exhibits high brightness of the emitted light and satisfactory durability in operation.

### BRIEF DESCRIPTION OF THE DRAWINGS

The foregoing advantages and features of the invention will become apparent upon reference to the following detailed description and the accompanying drawings, of which:

FIG. 1 is a sectional view of a color conversion filter substrate (a portion for one pixel) of an embodiment example according to the invention;

FIG. 2 is a sectional view of a color conversion filter substrate (a portion for one pixel) of another embodiment example according to the invention;

FIG. 3 is a sectional view of a multicolor light emitting device (a portion for one pixel) of an embodiment example according to the invention;

FIG. 4 is a graph showing the dependence of the brightness Le on the refractive index n₁ calculated according to Equation (5);

FIG. 5 is a graph showing an example of angular dependence of light emission from an organic EL device;

FIG. 6 is a graph showing dependence of red color brightness on operation time in the devices of Example 1 and Comparative Example 1;

FIG. 7 is a graph showing an example of angular dependence of the total amount of absorbed light in a color conversion filter; and

FIG. 8 is a graph showing dependence of the brightness of output emission light from a color conversion filter on the refractive index in a combination of an organic EL device and a color conversion filter.

### DETAILED DESCRIPTION OF SPECIFIC EMBODIMENTS

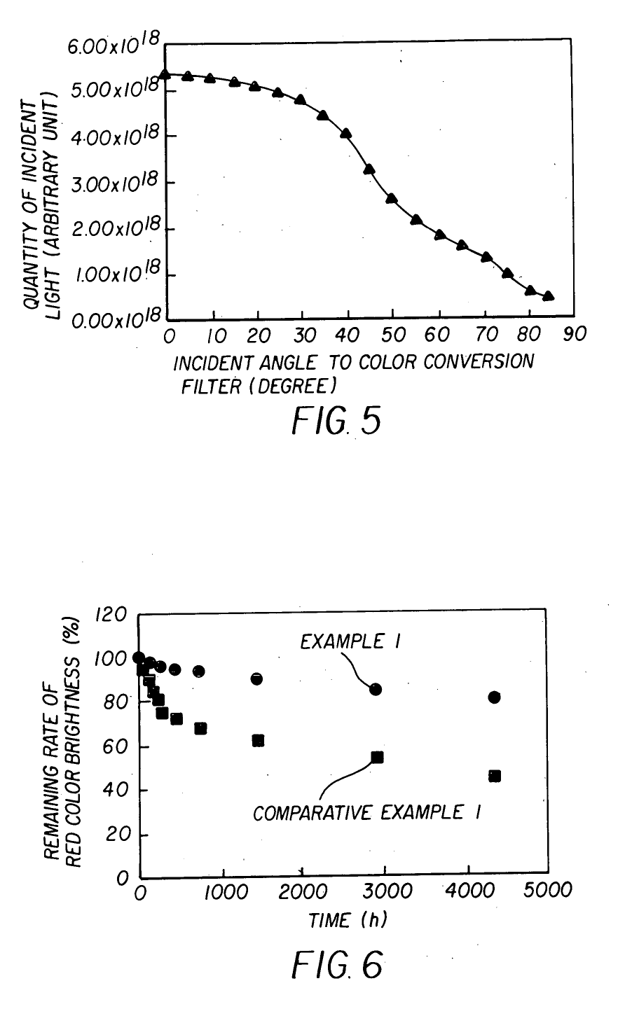

Based on extensive studies, the inventors have found that the angular dependence of light emission from an organic EL device is one of the most important issues in a combination of a color conversion filter substrate and a light source of an organic EL device. It was further found that the angular dependence of light emission from an organic EL device placed in the atmosphere is scarcely meaningful. In the case of the organic EL device placed in the atmosphere, the difference between the refractive indexes of the atmosphere and the material composing the organic EL device (particularly the transparent substrate, which has a light emitting plane) causes the total reflection at an interface of the light emitting plane and the atmosphere in the angular region greatly inclined from the normal to the light emitting plane. Therefore, the angular dependence of light emission can be measured in a very limited range of the whole angular range of the normal ±90° that is to be measured. Accordingly, the inventors soaked the organic EL device in oil having a refractive index equivalent to that of the transparent substrate having the light emitting plane and measured the light emission, to obtain angular dependence of the light emission from the organic EL device in a sufficiently wide angular range. FIG. 5 shows an example of the measured result. The angle of light emission in FIG. 5 is an angle from the normal to the light emitting plane (that is an incident angle to the color conversion filter).

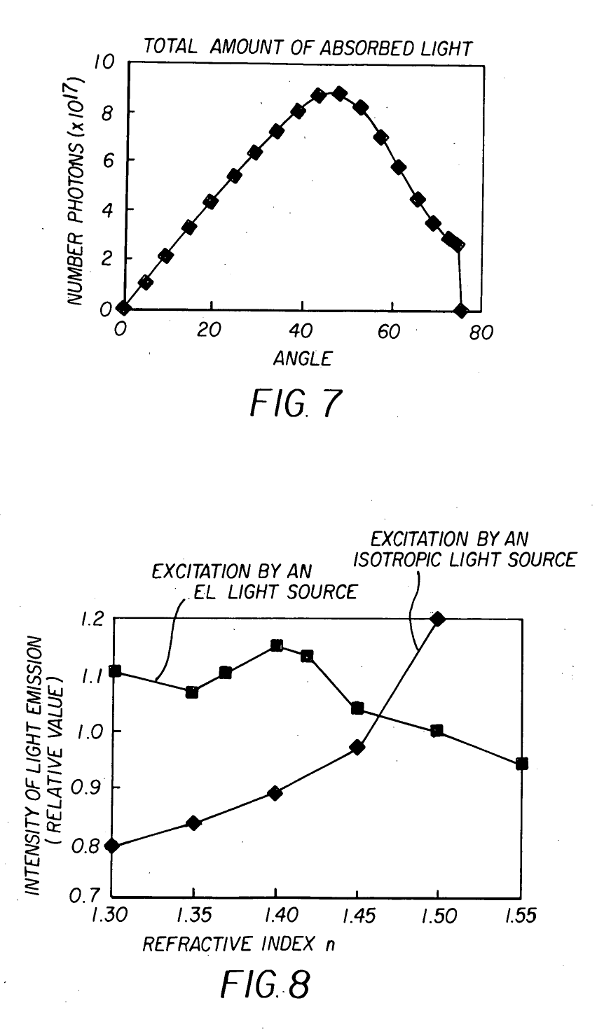

It can be seen from the data of FIG. 5 that the emission from the organic EL device significantly attenuates as the emission angle (an angle from the normal to the emitting plane) increases. In particular, it attenuates to less than 20% of the maximum value (the emission to the direction of normal) in the emission angles larger than 750. An exact theoretical explanation has not been established yet on the emission angle dependence of the fluorescent light intensity emitted from an organic EL device. However, the above-mentioned attenuation presumably is caused by a behavior that cannot be anticipated by classical optics in the large emission angle range and by the absorption occurring inside the organic EL device due to long optical path until emission within the EL device. The data of FIG. 5 is the light intensity emitted from the organic EL device in a minute angle region around each angle measured by a brightness meter and can be used to evaluate the amount of light contributing to excitation of the fluorescent dye in the color conversion filter. The amount of light contributing to excitation of the fluorescent dye in the color conversion filter is evaluated as a total amount of light absorbed by the color conversion filter at each angle that is obtained using the total amount of incident light to the color conversion filter at each angle, which is obtained by the data of FIG. 5 times sin θ/2π, and the optical path together with the absorption spectrum in the color conversion filter at each angle. FIG. 7 is a graph showing the total amount of light absorbed by the color conversion filter at each angle. It can be seen from FIG. 7 that the mount of light actually is incident to the color conversion filter from the organic EL device and excites the fluorescent dye in the filter is largest at an angle of about 45° and relatively small at angles larger and smaller than about 45°.

When the refractive index of the color conversion filter is decreased and the light emission from the organic EL device having a high refractive index falls to the color conversion filter having a low refractive index, the components of light having an incident angle larger than the critical angle do not enter the color conversion filter due to the total reflection at the interface. The amount of emitted light itself is small in the range of angles that cause total reflection, as clarified by the above measurement. So, even if those components do not enter the color conversion filter, the contribution to the intensity for excitation of the fluorescent dye in the color conversion filter (the intensity corresponds to P₁ in Equation (3)) is small, and thus, the contribution to the intensity of light after color conversion (this intensity corresponds to Pc in Equation (4)) is also small.

The effect of interference can be assumed to be insignificant since the fluorescent dyes that emit light in the color conversion filter are randomly distributed in the color conversion filter, and the thickness of the color conversion filter is a relatively large value of about 10 μm. Consequently, it is reasonable to assume the light emission in the color conversion filter is isotropic. It can be further understood that the amount of light emission from the color conversion filter extracted to the atmosphere surely increases if the refractive index of the color conversion filter (the index corresponds to n₁ in Equation (1)) is decreased.

As described above, with decrease of the refractive index of the color conversion filter, the intensity of light emission can be increased because of two accompanying phenomena. One of these is the slight decrease of incident light from the organic EL device, while the other is an enhancement of efficiency in extracting the light from the color conversion filter. A numerical study was made for the above described consideration about the dependence of the intensity of light emission on the refractive index. Using the measured values of the dependence of the intensity of light emission from the organic EL device on the angle of light emission (as shown in FIG. 5), the efficiency in the incidence to the color conversion filter, the quantity of the excited fluorescent dye in the color conversion filter, and the efficiency of extraction from the color conversion filter are obtained. From the product of these quantities, the dependence of the light intensity emitted from the color conversion filter on the refractive index (n) is obtained in a combination of the organic EL device and the color conversion filter. FIG. 8 shows the result. Also shown in FIG. 8 is the result of a calculation obtained by supposing an isotropic light source (Lambertian). FIG. 8 shows that while the decrease in the refractive index n of the color conversion filter directly leads to decrease of the intensity of light emission in the case of the isotropic light source, by contrast, in a light source of an organic EL device according to the invention, the decrease in the refractive index is rather advantageous. It has been clarified that by employing a refractive index of a color conversion filter from 1.30 to 1.50, the latter value being distinctly smaller than the refractive index of commonly used color conversion filter of about 1.55, the effect of enhancement of the efficiency of extracting light exceeds the effect of decrease of the amount of incident light, resulting in enhancement of the intensity of light emission. A refractive index of a color conversion filter in the invention is in the range of 1.30 to 1.50, preferably in the range of 1.33 to 1.50, more preferably in the range of 1.36 to 1.48, and most preferably in the range of 1.41 to 1.45.

A matrix for a color conversion filter giving a refractive index value in the above-specified range can be selected from organic polymer, silicone polymer, or an aerogel that is formed by dispersing microscopic air bubbles in these polymers. Among these materials, a straight type silicone polymer and a resin-modified type silicone polymer, both having a siloxane bond, can be preferably used. Those polymers allow stable dispersion of a fluorescent dye and improve or not impair the fluorescent light emitting ability of the fluorescent dye. Typical silicone polymers have a refractive index from 1.40 to 1.45.

In addition, various types of fluorescent dyes can be contained in a color conversion filter by using a resin-modified type silicone polymer that is a copolymer of a silicone polymer (or a monomer or an oligomer of silane derivatives) and an organic resin (or a monomer or an oligomer) selected from acrylic resins, epoxy resins, and urethane resins.

Of the dyes contained in a color conversion filter, ionic dyes such as rhodamines exhibit the solubility strongly dependent on the pH value in the matrix, and non-ionic dyes such as coumarins exhibit solubility dependent not on the pH but on aquaphilic or lipophilic property of the matrix. Consequently, dissolving both an ionic dye and a non-ionic dye into one type of matrix narrows the selection range for the matrix. It is very difficult to ensure all of mechanical property, optical property, and resistance to light of the dye in that narrow selection range. Therefore, plural types of dyes are contained advantageously in a mixture of plural types of matrices, each matrix being compatible with each type of dye. The resin-modified type silicone polymer that is a hybrid of the silicone and the organic resin can be specifically applied.

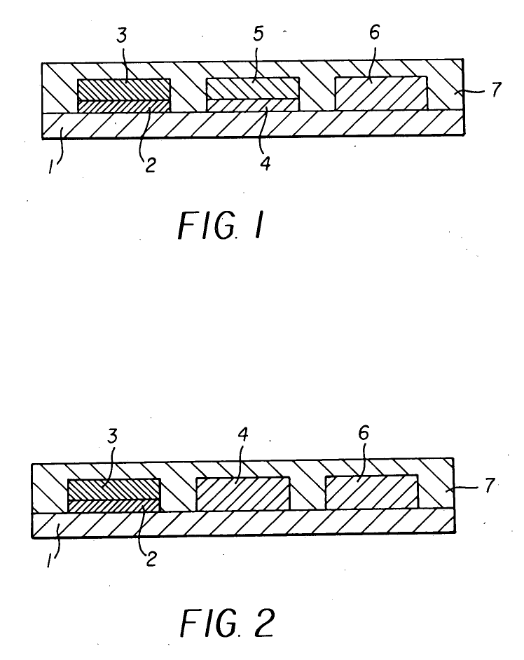

The aspects of embodiment of the present invention will be described in detail in the following. FIG. 1 is a schematic sectional view of an example of a color conversion filter substrate according to the invention. Two of the three colors are emitted through the color conversion filter. The figure shows a structure in which the surface of the color conversion filter is covered with a protective layer. FIG. 2 shows an example in which only one color is emitted through a color conversion filter, and shows a structure having the surface of the color conversion filter covered with a protective layer as in FIG. 1.

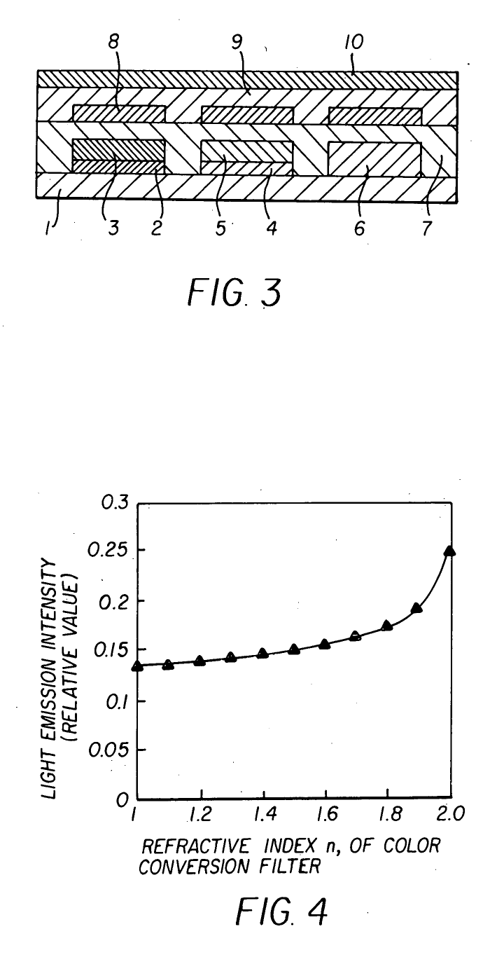

FIG. 3 is a schematic sectional view of an example of a multicolor light emitting device of the invention that is a combination of a color conversion filter substrate according to the invention and a light emitting body of an organic EL device.

The following describes aspects of an embodiment of each construction element.

Transparent Support Substrate 1

Transparent support substrate 1 in FIG. 1 and FIG. 2 is sufficient if the support substrate has a high transmissivity to the visible light and does not degrade performance of a color conversion filter or a multicolor light emitting device in the process to fabricate the color conversion filter and the multicolor light emitting device. The support substrate can be a glass substrate, a plastic substrate, or a film.

Color Filters 2, 4, and 6

At least two types of color filters each transmitting light in a different wavelength range are independently arranged in a color conversion filter substrate according to the invention. Each of color filters 2, 4, and 6 in FIG. 1 and FIG. 2 has a different transmission wavelength range. For example, color filter 2 is a red color filter transmitting light in the red color region; color filter 4 is a green color filter transmitting light in the green color region; and color filter 6 is a blue color filter transmitting light in the blue color region. Color filters 2, 4, and 6 for the three colors improve the color purity of the light emitted from a light emitting body or the light that has been converted to a different wavelength in a color conversion filter described later. The color filters can use those employed in displays including liquid crystal display. The color filter is generally composed of a polymer binder and a pigment dispersed in the binder.

Color Conversion Filters 3 and 5

A color conversion filter substrate of the invention comprises at least one type of color filter. A color conversion filter in the invention consists of a matrix and a substance such as a fluorescent dye dispersed in the matrix, the substance absorbing light in a first wavelength region and emitting light in a wavelength region different from the absorbed wavelength region. The matrix in the invention is preferably a silicone polymer or a hybrid material (resin-modified type silicone polymer) of a silicone polymer and an organic polymer resin.

Each of color conversion filters 3 and 5 absorbs a part of the incident light and emits light with a different wavelength. For example, color conversion filter 3 is a red color conversion filter that emits red light, and color conversion filter 5 is a green color conversion filter that emits green light.

When a color conversion filter is used with a color filter for a corresponding color, the color conversion filter is preferably laminated on the color filter, for example, red color conversion filter 3 is laminated on red color filter 2 in FIG. 1. When full color display is desired in combination with a light emitting member that emits ultraviolet light or blue light, it is favorable to use both red color conversion filter 3 on red color filter 2 and green color conversion filter 5 on green color filter 4, as shown in FIG. 1. When a full color display is desired in combination with a light emitting member that emits blue-green light and the light from the light emitting member includes a sufficient quantity of green light component, a structure can be taken in which only red color conversion filter 3 on red color filter 2 is disposed and a green color conversion filter is omitted, as shown in FIG. 2.

Fluorescent Dye

A fluorescent dye that absorbs light in the blue color to blue-green color region emitted from a light emitting body (including an organic EL device) and emits fluorescent light in the red color region can be selected from, for example, rhodamine dyes such as rhodamine B, rhodamine 6G, rhodamine 3B, rhodamine 101, rhodamine 110, sulforhodamine, basic violet 11, and basic red 2, cyanine dyes, pyridine dyes such as 1-ethyl-2-[4-(p-dimethylaminophenyl)-13-butadienyl]-pyridium perchlorate (pyridine 1), and oxazine dyes. In addition, a material selected from various dyestuffs (including direct dyes, acid dyes, basic dyes, and disperse dyes) can be used if it has fluorescent properties.

A fluorescent dye that absorbs light in the blue color to blue-green color region emitted from a light emitting body and emits fluorescent light in the green color region can be selected from, for example, coumarin dyes such as 3-(2′-benxothiazole)-7-diethylamino-coumarin (coumarin 6), 3-(2′-benzoimidazolyl)-7-N,N-diethylamino-coumarin (coumarin 7), 3-(2′-N-methylbenzoimidazolyl)-7-N,N-diethylamino-coumarin (coumarin 30), and 2,3,5,6-1H,4H-tetrahydro-8-trifluoromethylquinolizine (9,9a,1-gh) coumarin (coumarin 153), basic yellow 51 that is a dyestuff of coumarin dye, and naphthalimide dyes such as solvent yellow 11 and solvent yellow 116. In addition, a material selected from various dyestuffs (including direct dyes, acid dyes, basic dyes, and disperse dyes) can be used if it has fluorescent properties.

Matrix

The following describes in detail the straight type silicone polymer and the resin-modified type silicone polymer used for the matrix. The straight type silicone polymer includes a sole active ingredient of silicone having, similarly to the other silicone products, a principal chain of —Si—O—Si— bonds and side chains of alkyl groups such as methyl groups or aromatic groups such as phenyl groups. After curing, the polymer forms a three dimensional crosslinked structure with a very high crosslinking density and has the advantage of forming a hard film.

The straight type silicone polymer is polymerized by hydrolytic condensation from the monomers of silane derivatives as shown in Formula (IV), and has a branched chain structure. The branched chain structure is developed and the crosslinking density is increased by containing large fraction of the monomers of three functional groups (the case of n=1) and the monomers of four functional groups (the case of n=0) in the monomers of Formula (IV).
XnSi(OR)₄₋ₙ (IV)

In Formula (IV), X represents a methyl group or a phenyl group, R represents a hydrogen atom, an alkyl group, an aryl group, or an aryl group optionally having a substituent. If the monomer of Formula (IV) has a plurality of X or R, the X or R can be identical or different from each other. “n” is an integer of 0, 1, or 2, preferably 1 or 2. A small value of “n” generally increases the number of crosslinking points and increases hardness.

A straight type silicone polymer contains the structural unit represented by the Formulas (I), (II), and/or (III), wherein each of R₁, R₂, and R₃ represents an alkyl group or a phenyl group. The straight type silicone polymer can contain one or more of the structural units of Formulas (I), (II), and (III).
Chemical Formula 1

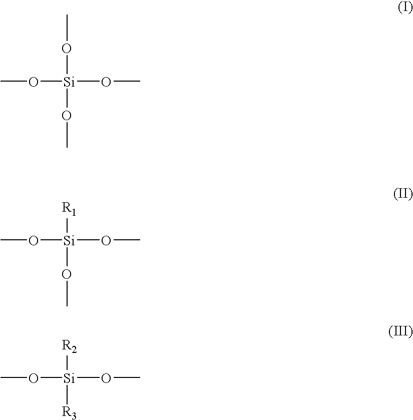

A methyl silicone polymer in which each of R₁, R₂, and R₃ is a methyl group is composed of the monomers of Formula (IV) in which X is a methyl group. The methyl silicone polymer contains a large amount of silanol groups Si—OH obtained by hydrolysis of Si—OR in the monomer (IV), and has an affinity for water-alcohol. The methyl silicone polymer forms an extremely hard film by combining silica sol or alumina sol in a solution, and thus, can be used as a hard coat agent for surface hardening of plastics. A phenyl silicone polymer in which each of R₁, R₂, and R₃ is a phenyl group is composed of the monomers of Formula (IV) in which X is a phenyl group. The phenyl silicone polymer has a better film strength than the methyl silicone polymer.

Specific examples of the straight type silicone resin include KP-85, KP-64, X-12-2206, X-12-2396, X-12-2397 (manufactured by Shin-etsu Chemical Co, Ltd.) and SH804, SH805, SH806A, SH840, SR2400 (manufactured by Toray Dow Corning Silicone Co., Ltd.), but the invention is not limited to these materials.

A resin-modified type silicone polymer is generally formed by block copolymerization or graft copolymerization between silicone crosslinker and organic resin, or by condensation polymerization through an ether bond. More specifically, a resin-modified type silicone polymer is a reaction product between an organic resin that has an active functional group such as —OH group, —COOH group, or —O— (epoxy) group and a silicone resin that has various molecular weights and contains plenty of alkoxy groups such as a silanol group, or methoxy group on a relative basis. The organic resin can be selected from acrylic resin, urethane resin, epoxy resin, alkyd resin, polyester resin, polystyrene resin, polyacrylonitrile resin, polycarbonate resin, and the like.

The resin-modified type silicone polymer is known as an organic-inorganic hybrid material that exhibits the characteristics of an organic resin, namely, flexibility, adhesivity, water-resisting property, film-forming ability, and electric insulation property, together with the characteristics of a silicone resin, namely, excellent heat resistance and stability in environment. Actually proposed resin-modified type silicone polymers include imide-modified silicone resin (see Japanese Unexamined Patent Application Publication No. H08-005829) and silicone-modified polyester resin (see Japanese Unexamined Patent Application Publication No. H07-333418). The resin-modified type silicone polymer is a useful matrix exhibiting compatibility with both ionic dyestuffs and non-ionic dyestuffs. Nevertheless, organic resins react with a dye in an excited state and deactivate the function of the dye. So, the amount of organic resin must be limited to a minimum quantity, and preferably, the proportion in solid component of the organic resin is in a range of 5 wt % to 30 wt % of the total weight of the polymer.

A resin-modified type silicone polymer can be composed, for example, by the reaction between the monomer of Formula (IV) and an alkoxysilyl group after the production of an organic resin using monomers having the alkoxysilyl group. The alkoxysilyl group can have one to three alkoxyl groups.

Alternatively, the hybridization of organic and inorganic substances can be readily performed using a silane compound, generally referred to as a silane coupling agent, having a structure represented by Formula (V) below.
YₙSi(OR)₄₋ₙ (V)
where Y represents an organic group having a substituent that reacts with an organic resin, and can be a mercapto group, an azido group, an amino group, an epoxy group, an acrylic group, a methacrylic group, an acryloxy group, or a methacryloxy group; R represents a hydrogen atom, an alkyl group, an aryl group, or an aryl group optionally having a substituent; and n is an integer from 1 to 3, preferably 2 or 3. First, the organic resin reacts with the silane compound of Formula (V) at the substituent on the Y, then bonds to the silicone resin through the Si—OR group of the Formula (V).

The silane compound having the structure of Formula (V) can be selected from products commercially available from several manufacturers including SH6020, SZ6030, SH6040, and SZ6075 (products of Toray Dow Corning Silicone Co., Ltd.), for example, but the invention is not limited to these materials. Specific examples of the resin-modified type silicone polymer include SR2107, SR2115, and SR2145 (products of Toray Dow Corning Silicone Co., Ltd.), for example, but the invention is not limited to these materials.

Protective Layer 7

A protective layer is optionally provided for the purpose of, as its name suggests, protecting a color conversion filter, and for the purpose of smoothing the film surface. Protective layer 7 is formed of a highly light transparent material and must be fabricated with a process that does not deteriorate the color conversion filter. When an inorganic gas barrier film or an electrode of a transparent conductive film is formed on protective layer 7, protective layer 7 additionally needs to be resistant to sputtering.

The protective layer having smoothing as an additional purpose generally is formed by a coating method. A commonly applied material is produced by treating a photochemically curing resin or a photochemically and thermally curing resin with light and/or heat, and polymerizing or crosslinking utilizing the generated radicals or ions, to produce an insoluble and infusible material. The photochemically curing resin or photochemically and thermally curing resin is desired to be soluble in an organic solvent or an alkali solution in a stage before the curing.

The photochemically curing resins or photochemically and thermally curing resins include: (1) materials obtained by photochemically or thermally treating a film composed of acrylic multifunctional monomers or oligomers having plural acroyl groups or methacroyl groups and initiators of photochemical or thermal polymerization, and by generating photochemical or thermal radicals to perform polymerization; (2) materials obtained by photochemically or thermally treating a substance composed of poly(vinyl cinnamate) and a sensitizer, and by dimerization and crosslinking; (3) materials obtained by photochemically or thermally treating a film composed of straight chain or cyclic olefin and bisazide to generate nitrene, and by crosslinking with the olefin; and (4) materials obtained by photochemically or thermally treating a film composed of monomers having an epoxy group and a photochemical oxygenation agent and generating an acid (cation), to perform polymerization. The photochemically curing or photochemically and thermally curing resins of (1) in particular, are preferred because of their ability for high precision patterning and their reliability, including solvent resistance and heat resistance.

Protective layer 7 can be formed of a thermoplastic resin selected from polycarbonate (PC), poly(ethylene terephthalate) (PET), polyether sulfone, poly(vinyl butyral), polyphenylene ether, polyamide, polyether imide, norbornene resin, acrylic resin, methacrylic resin, isobutylene-maleic anhydride copolymer resin, and cyclic olefin; or can be formed of a thermosetting resin selected from epoxy resin, phenol resin, urethane resin, acrylic resin, vinyl ester resin, imide resin, urea resin, and melamine resin. In addition, the protective layer can be composed of a straight type silicone polymer, or a resin-modified type silicone polymer that is formed of a three functional or four functional alkoxysilane and a polymer such as polystyrene, polyacrylonitrile, or polycarbonate.

When a color conversion filter substrate of the invention is combined with an organic light emitting device, a gas barrier layer (not shown in the figures) can be laminated on the surface of the protective layer for the purpose of protecting the organic light emitting device against the moisture generated in the color conversion filter substrate. The gas barrier must be a transparent and dense film free of a pinhole. The gas barrier layer can be composed of inorganic oxide or inorganic nitride such as SiOₓ, SiNₓ, SiNₓO_{y}, AlOₓ, TiOₓ, TaOₓ, or ZnOₓ. The gas barrier can be formed by a commonly used method such as sputtering, CVD, vacuum evaporation, dipping, without any special limitation.

Organic EL Device

An organic EL device, a light emitting body as shown in FIG. 3, comprises a pair of electrodes (first electrode 8 and second electrode 10) and organic EL layer 9 sandwiched between the electrodes. The organic EL layer comprises at least an organic light emitting layer and, as required, a hole injection layer, a hole transport layer, an electron transport layer and/or an electron injection layer. Optionally, a hole injection transport layer that serves both hole injection and hole transport functions or an electron injection transport layer that serves both electron injection and electron transport functions can be used. An organic EL device can have one of the following specific layer structures:
(1) anode/organic light emitting layer/cathode
(2) anode/hole injection layer/organic light emitting layer/cathode
(3) anode/organic light emitting layer/electron injection layer/cathode
(4) anode/hole injection layer/organic light emitting layer/electron injection layer/cathode
(5) anode/hole transport layer/organic light emitting layer/electron injection layer/cathode
(6) anode/hole injection layer/hole transport layer/organic light emitting layer/electron injection layer/cathode
(7) anode/hole injection layer/hole transport layer/organic light emitting layer/electron transport layer/electron injection layer/cathode.

In the above listed layer structures, at least one of the anode and cathode is preferably transparent to the light in the wavelength range emitted by the organic EL device. The organic EL device emits light through the transparent electrode and illuminates the color conversion filter or the color filter. It is known in the art that a transparent anode can be readily obtained. So, it is preferred in the present invention, too, to use the first electrode 8 for an anode and to use the second electrode 10 for a cathode.

Materials of the layers in the layer structures can be composed of known materials. An organic light emitting layer to obtain the emission in blue to blue-green color, for example, can be composed of a material selected from fluorescent whitening agents of benzothiazole, benzoimidazole, and benzoxazole, metal chelate oxonium compounds, styrylbenzene compounds, and aromatic dimethylidine compounds.

The patterns of the first electrodes and the second electrodes, as shown in FIG. 3, may have each shape of parallel stripes, and the two patterns may cross each other. In that case, the organic EL device of the invention allows matrix drive, in which on application of a voltage to one stripe of the anode and a voltage to one stripe of the cathode, the organic EL layer emit light at the crossing point of the stripes. By applying a voltage to a selected stripe of the first electrode 8 and a voltage to a selected stripe of the second electrode 10, the light emission occurs at a location of a specific color conversion filter and/or color filter.

Alternatively, the first electrode 8 may be a uniform planar electrode without the stripe pattern and the second electrode 10 can be patterned consisting of the elements each corresponding to a pixel. In that case, switching elements each corresponding to a pixel are provided and connected to the elements of the second electrode 10 each corresponding to a pixel in the one to one correspondence manner, allowing so-called active matrix drive.

### EXAMPLES

A specific example employing a patterning method of the present invention is described in the following with reference to the drawings.

### Example 1

Color Filter

On substrate 1 of 1737 glass manufactured by Corning Corporation, stripe patterns of red color filter 2, green color filter 4, and blue color filter 6 were formed, each having a width of 0.10 mm and a pitch of 0.33 mm without overlapping, using respective materials of CR7001, CG7001, and CB7001 manufactured by Fujifilm Arch Co., Ltd. by means of a lithography method. Thickness of the color filters was 1.0 μm. Then, only on blue color filter 6 of CB7001, a transparent stripe pattern was formed with a thickness of 10 μm, a width of 0.10 mm, and a pitch of 0.33 mm using V259PAP5 manufactured by Nippon Steel Chemical Co., Ltd. by means of a photolithography method. This pattern was formed to avoid the difference among film thicknesses for three colors when the color conversion filters for red and green colors were formed.

Green Color Conversion Filter

A fluorescent dye of coumarin 6 (0.7 parts by weight) was dissolved in 120 parts by weight of a solvent of propylene glycol monoethy acetate (PGMEA). To this solution, 100 parts by weight of V259PAP5 manufactured by Nippon Steel Chemical Co., Ltd. was added and dissolved to obtain a coating liquid. Using this coating liquid, a pattern having a width of 0.1 mm, a pitch of 0.33 mm, and a thickness of 10 μm was formed on the green color filter by means of a photolithography method, to obtain green color conversion filter 5.

Red Color Conversion Filter

A fluorescent dye of rhodamine 6G (0.3 parts by weight) and basic violet 11 (0.3 parts by weight) was added to and dissolved in 100 parts by weight of a silicone polymer KP854 manufactured by Shin-etsu Chemical Co., Ltd. to obtain a coating liquid. Using this coating liquid, a pattern having a width of 0.1 mm, a pitch of 0.33 mm, and a thickness of 10 μm was formed by means of a photolithography method, to obtain red color conversion filter 3. The refractive index of red color conversion filter 3 measured by an ellipsometry method was 1.43.

Forming a Protective Layer

Protective layer 7 was formed on the color conversion filters and the color filters using V259PAP5 manufactured by Nippon Steel Chemical Co., Ltd. A thickness of protective layer 7 was 5 μm.

Forming a Gas Barrier Layer

A gas barrier layer was obtained of a SiOx film of 0.5 μm by means of a sputtering method. The sputtering apparatus was of an RF planar magnetron type and the target used was SiO₂. The sputtering gas in the deposition process was argon. The substrate temperature in the forming process was 80° C.

Fabrication of an Organic EL Device

An organic EL device as shown in FIG. 3 was formed to obtain a multicolor light emitting device by sequentially forming on the filter portion fabricated as described above: anode/organic EL layer (consisting of four layers: hole injection layer/hole transport layer/organic light emitting layer/electron injection layer)/cathode.

First, a transparent electrode (ITO) was deposited on the entire surface of the gas barrier layer, which is an outermost layer of the filter portion, by sputtering. On the ITO, a resist agent OFRP-800 manufactured by Tokyo Ohka Kogyo Co., Ltd. was applied, followed by pattering by means of photolithography, to obtain first electrode 8 (anode) consisting of a stripe pattern having a width of 0.094 mm, a pitch of 0.10 mm, and a thickness of 100 nm disposed at the light emitting location for each color (red green and blue).

The substrate having the anode formed thereon was installed in a resistance-heating evaporation apparatus, and a hole injection layer, a hole transport layer, an organic light emitting layer, and an electron injection layer were subsequently deposited while maintaining the vacuum. The pressure in the vacuum chamber in the deposition process was 1×10⁻⁴ Pa. For the hole injection layer, copper phthalocyanine (CuPc) was laminated to a thickness of 100 nm. For the hole transport layer, 4,4′-bis[N-(1-naphtyl)-N-phenylamino]biphenyl (α-NPD) was laminated to a thickness of 20 nm. For the light emitting layer, 4,4′-bis(2,2′-diphenylvinyl)biphenyl (DPVBi) was laminated to a thickness of 30 nm. For the electron injection layer, aluminum chelate (Alq₃) was laminated to a thickness of 20 nm.

Maintaining the vacuum, a layer 200 nm thick of Mg/Ag (weight ratio of 10:1) was deposited using a mask to form a stripe pattern with a width of 0.30 mm and a pitch of 0.33 mm gap orthogonal to the lines of the first electrode 8 (ITO), to produce second electrode 10 (cathode).

The thus obtained organic light emitting device was sealed with a sealing glass (not shown in the figure) and a UV curing adhesive in a glove box under a dry nitrogen atmosphere (both oxygen concentration and moisture concentration were not larger than 10 ppm).

### Comparative Example 1

A multicolor light emitting device was formed in the same manner as in Example 1 except that in fabrication of a red color conversion filter, fluorescent dyes of rhodamine 6G (0.3 parts by weight) and basic violet 11 (0.3 parts by weight) were added to and dissolved in 100 parts by weight of V259PAP5 manufactured by Nippon Steel Chemical Co., Ltd. to prepare a coating liquid, and a red color conversion filter was formed using this coating liquid by means of a photolithography method. The refractive index of the red color conversion filter measured by an ellipsometry method was 1.55.

Evaluation

The multicolor light emitting devices formed in the Example and Comparative Example were driven at a constant current, and the brightness in each color was measured in a dependence on the driving time. Table 1 shows the initial brightness of red color emission in the devices. FIG. 6 shows the brightness of red color light in the devices in dependences on the driving time.

TABLE 1
Initial brightness of red color light emission of the devices

| | brightness of red light emission |
|---|---|
| | (cd/m²) |
| Example 1 | 35 |
| Comparative Example 1 | 19 |

Table 1 demonstrates that the initial brightness of red color light emission of the multicolor light emitting device of Example 1 according to the invention is remarkably large as compared with the device of Comparative Example 1. This is an effect of improvement in the efficiency of light extraction achieved by the use of a silicone polymer having a specified refractive index for the matrix of the red color conversion filter. FIG. 6 demonstrates that the remaining rate of brightness of red color emission is significantly improved in Example 1 that uses a color conversion filter substrate according to the invention as compared with Comparative Example 1. This is a result of effective suppression of the degradation due to driving of the dyes in the red color conversion filter.

Thus, a color conversion filter substrate and a multicolor light emitting device employing the substrate have been described according to the present invention. Many modifications and variations may be made to the techniques and structures described and illustrated herein without departing from the spirit and scope of the invention. Accordingly, it should be understood that the methods and devices described herein are illustrative only and are not limiting upon the scope of the invention.

What is claimed is:

1. A color conversion filter substrate comprising:
a transparent support substrate,
at least two types of color filters independently arranged on said substrate, each transmitting light in a different wavelength range, and
at least one color conversion filter absorbing light with a wavelength and emitting light containing a wavelength different from the absorbed wavelength,
wherein the color conversion filter includes a dye dispersed in a matrix, the dye absorbing light with a wavelength and emitting light containing a wavelength different from the absorbed wavelength, and the color conversion filter has a refractive index in a range of 1.30 to 1.48.

2. The color conversion filter substrate according to claim 1, wherein the matrix contains a straight silicone polymer or a resin-modified silicone polymer.

3. The color conversion filter substrate according to claim 2, wherein the straight silicone polymer consists of at least one structural unit selected from structural units represented by formulas (I), (II), and (III), wherein each of R₁, R₂, and R₃ represents an alkyl group or a phenyl group:

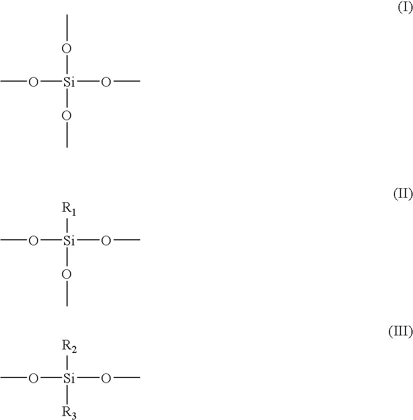

4. The color conversion filter substrate according to claim 1, wherein at least one of the color conversion filters contains at least one rhodamine dye.

5. A multicolor light emitting device formed in combination of the color conversion filter substrate defined by claim 1 and an organic EL device.

6. A method of manufacturing a multicolor light emitting device comprising steps of:
preparing the color conversion filter substrate defined by claim 1;
forming a protective layer on the color conversion filter of the color conversion filter substrate;
forming a gas barrier layer on the protective layer; and
forming an organic EL device on the gas barrier layer.
